(19) United States
(12) Patent Application Publication
(10) Pub. No.: US 2009/0138220 A1
(43) Pub. Date: May 28, 2009

(54) Power-aware line intervention for a multiprocessor directory-based coherency protocol

(76) Inventors: Robert H. Bell, JR., Austin, TX (US); Louis B. Capps, JR., Georgetown, TX (US); Thomas E. Cook, Essex Junction, VT (US); Michael J. Shapiro, Austin, TX (US); Naresh Nayar, Rochester, MN (US)

Correspondence Address: HAMILTON & TERRILE, LLP;IBM Austin, P.O. BOX 203518, AUSTIN, TX, 78720, US

(21) Appl. No.: 11/946,551

(22) Filed: Nov. 28, 2007

(51) Int. Cl. G01R 21/02; G06F 12/08

(52) U.S. Cl. 702/60; 711/130; 711/E12.038

(57) ABSTRACT

A directory-based coherency method, system and program are provided for intervening a requested cache line from a plurality of candidate memory sources in a multiprocessor system on the basis of the sensed temperature or power dissipation value at each memory source. By providing temperature or power dissipation sensors in each of the candidate memory sources (e.g., at cores, cache memories, memory controller, etc.) that share a requested cache line, control logic may be used to determine which memory source should source the cache line by using the power sensor signals to signal only the memory source with acceptable power dissipation to provide the cache line to the requester.

### BACKGROUND OF THE INVENTION

1. Field of the Invention

The present invention is directed in general to the field of data processing systems. In one aspect, the present invention relates to cache memory management within multiprocessor systems.

2. Description of the Related Art

In multi-processor computer systems having one or more levels of cache memory at each processor, cache coherency is typically maintained across such systems using a snoop protocol or a directory-based protocol. Where a snoop protocol is used to provide system coherency for cache lines with existing multi-processor systems, there is a large amount of sharing of cache lines, upwards of 30% of all requests in some cases. This may be understood with reference to a multi-core system, such as the POWER5/6 which uses a snoop protocol to maintain coherency. In such a system, lines requested for a read operation by a first core that are already being accessed (for either reads or previously for writes) by a second core can be marked as shared in the second core, forwarded or intervened to the first core, and also marked as shared in the first core. Both cores then access the shared lines for reads in parallel, without further communication. This protocol can result in multiple cores sharing the same line so that when another core attempts to access (for read shared or exclusive) a line that is already shared by two or more cores, a choice must be made of which core provides the shared copy. A typical cache allocation model would provide the line based on some centralized control heuristic such as, for example, deciding that the core physically closest to the requesting core could provide the line. In some implementations, a specific core's version of the shared line is marked as the shared copy that will be provided for future requests, thereby reducing the time required to access the cache line.

While memory access speed has historically been a key design objective, in today's multiprocessors, power dissipation is an increasingly important design constraint that must be considered, especially when the power dissipation can be different at each core in a multiple heterogeneous core system, or when homogeneous cores not being utilized perfectly symmetrically, the power dissipation can be different at each core. In addition, power dissipation (and hence core temperature) can increase when some level of the cache hierarchy (e.g., the L2 cache in a first processing unit) is accessed to intervene shared lines to other cores or to an L2 cache in another processing unit. As will be appreciated, such power dissipation occurs when powering up the control or the sub-arrays of the cache, when reading the line out of the cache, and when forwarding the line across a bus to the requesting core. In some cases, one or more of the cores and their associated cache hierarchies may be dissipating significant power, and it can also be the case that all of the cores are “hot” when they are all dissipating significant power.

While attempts have been made to control the “hot core” problem, such as powering down a “hot” core or moving jobs and threads to “cool” cores (i.e., cores that are not consuming excessive power), such solutions do not provide a mechanism for coherently sourcing a cache line to a requesting core, and otherwise impose an undue limit on the processing capability by powering down the hot core(s). Accordingly, there is a need for a system and method for controlling the effects of power dissipation in a multiprocessor system by efficiently and quickly sourcing cache lines to a requesting core. In addition, there is a need for a multi-core system and method to provide system coherency for cache line requests which takes into account the power consumption status of individual cores. Further limitations and disadvantages of conventional cache sourcing solutions will become apparent to one of skill in the art after reviewing the remainder of the present application with reference to the drawings and detailed description which follow.

### SUMMARY OF THE INVENTION

A power-aware line intervention system and methodology are provided for a multiprocessor system which uses a directory-based coherency protocol wherein requested cache lines are sourced from a plurality of memory sources on the basis of the sensed temperature or power dissipation at each memory source. By providing temperature or power dissipation sensors in each of a plurality of memory sources (e.g., at cores, cache memories, memory controller, etc.) that share a requested line, control logic may be used to determine which memory source should source the line by using the power sensor signals to signal only the memory source with acceptable power dissipation to provide the line to the requester. In selected embodiments, core temperature sensors, such as a diode, are positioned and integrated within individual memory sources to provide signals to the control heuristic to indicate a particular core or memory controller should be disqualified from providing a line to a requesting core, though without necessarily powering down the high-power core. For example, if two cores each shared a requested line in their respective cache memories, the core that is physically close to the requester would then provide a copy of the line only if it is not already at maximum threshold with respect to power. Otherwise, the line would be provided by another sharing core or the memory controller buffers. When a directory-based coherency protocol system is used to maintain cache coherency, the power sensor signals may be used whether the requesting core wants the line shared or exclusive. In selected implementations of a directory-based coherency protocol system, a request for exclusive access to a cache line is sent to a centralized directory which causes the higher-power cores to invalidate their copies of the line, so that the requested cache line would be sourced from the lower-power core or memory controller.

In accordance with various embodiments, a requested cache line may be intervened in a multiprocessor data processing system under software control using the methodologies and/or apparatuses described herein, which may be implemented in a data processing system with computer program code comprising computer executable instructions. In whatever form implemented, a request for a first cache line is generated during operation of the multiprocessor data processing system. In response, one or more memory sources (e.g., at cores, cache memories, memory controller, etc.) which store a copy of the requested first cache line are identified. In addition, temperature or power dissipation values for each of the plurality of memory sources are collected, such as by monitoring a sensor at each memory source for measuring a temperature or power dissipation value associated with said memory source. Based on the collected temperature or power dissipation values, a first memory source is selected from the plurality of memory sources to intervene the requested first cache line, where the first memory source is selected at least in part based on having an acceptable temperature or power dissipation value. For example, the first memory source may be selected by selecting memory source having a first temperature or power dissipation value that is lower than a second temperature or power dissipation value associated with another memory source. By comparing a first temperature or power dissipation value that is associated with the first memory source to one or more other temperature or power dissipation values associated with one or more other memory sources, a cool memory source is thereby selected. On the other hand, if none of the plurality of cache memories has an acceptable temperature or power dissipation value, a memory controller having an acceptable temperature or power dissipation value is selected to intervene the requested first cache line. To implement a directory-based protocol, a first memory source is selected by maintaining at a centralized directory line state information, along with temperature or power dissipation values, for each of the plurality of memory sources; selecting a first memory source to intervene the requested first cache line, where the first memory source is selected at least in part based on having an acceptable temperature or power dissipation value; and sending from the centralized directory a selection message to instruct the first memory source to intervene the requested first cache line.

### BRIEF DESCRIPTION OF THE DRAWINGS

Selected embodiments of the present invention may be understood, and its numerous objects, features and advantages obtained, when the following detailed description is considered in conjunction with the following drawings, in which:

FIG. 1 illustrates a symmetric multi-processor computer architecture in which selected embodiments of the present invention may be implemented;

FIG. 2 illustrates in simplified form the signal flow between various cores in a multi-processor system which implements power-aware line intervention in a directory-based coherency protocol for monitoring cache consistency;

FIG. 3 is an example table listing of directory responses to the requesting and sending cores in response to a read or write request from a requesting core in a multi-processor system which implements power-aware line intervention in selected directory-based coherency protocol embodiments of the present invention; and

FIG. 4 is a logical flowchart of the directory-based coherency protocol steps used to source a cache line to a requesting core from a plurality of memory sources in a multi-processor system based on the power or thermal conditions associated with the memory resources.

### DETAILED DESCRIPTION

A directory-based coherency protocol method, system and program are disclosed for coherently sourcing cache lines to a requesting core from a plurality of sources that each share the requested cache line on the basis of temperature and/or power signals sensed at each source so that only the source with an acceptable power dissipation or temperature is signaled to provide the requested line. To sense the temperature or power dissipation at each core of a multi-core chip, a diode is placed at each core on the chip as a temperature sensor. Where the diode output voltage will vary from 0.5-1.0V for a typical temperature range of 20 to 100 C, the output voltage is monitored and can be stored in a register for use by a control heuristic to select the source core from the cores having a temperature below a predetermined threshold. The disclosed techniques can be used in connection with a directory-based coherency protocol to source cache lines on a multiprocessor chip. In a directory-based coherency protocol in a multiprocessor, the request from a core is sent to a centralized directory, usually located near the memory controller, that keeps a list of all the cores that have a copy of the line and the line states. The centralized directory logic selects which core will return the line and signals that core to intervene the line to the requester based on the temperature and/or power signals sensed at each core so that only the core with an acceptable power dissipation or temperature is signaled to provide the requested line. As described more fully below, the term “core” as used herein refers to an individual processor's core logic, the L1 cache, the L2 cache and/or an L3 cache associated therewith.

Various illustrative embodiments of the present invention will now be described in detail with reference to the accompanying figures. It will be understood that the flowchart illustrations and/or block diagrams described herein can be implemented in whole or in part by dedicated hardware circuits, firmware and/or computer program instructions which are provided to a processor of a general purpose computer, special purpose computer, or other programmable data processing apparatus to produce a machine, such that the instructions (which execute via the processor of the computer or other programmable data processing apparatus) implement the functions/acts specified in the flowchart and/or block diagram block or blocks. In addition, while various details are set forth in the following description, it will be appreciated that the present invention may be practiced without these specific details, and that numerous implementation-specific decisions may be made to the invention described herein to achieve the device designer's specific goals, such as compliance with technology or design-related constraints, which will vary from one implementation to another. While such a development effort might be complex and time-consuming, it would nevertheless be a routine undertaking for those of ordinary skill in the art having the benefit of this disclosure. For example, selected aspects are shown in block diagram form, rather than in detail, in order to avoid limiting or obscuring the present invention. In addition, some portions of the detailed descriptions provided herein are presented in terms of algorithms or operations on data within a computer memory. Such descriptions and representations are used by those skilled in the art to describe and convey the substance of their work to others skilled in the art. Various illustrative embodiments of the present invention will now be described in detail below with reference to the figures.

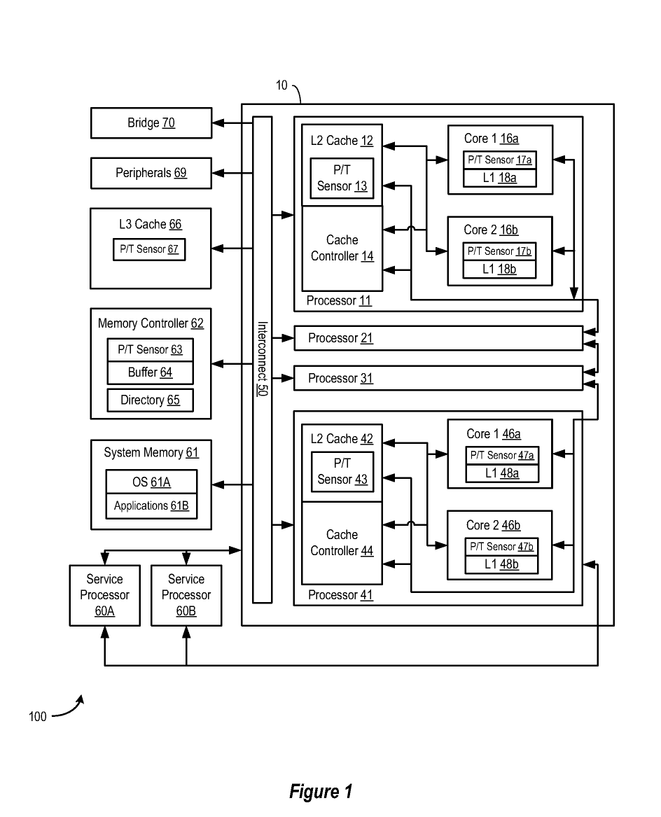

Referring to FIG. 1, a diagram depicts an example architecture of a symmetric multi-processor computer system 100 in which selected embodiments of the present invention may be implemented. The computer system 100 has one or more processing units arranged in one or more processor groups, and as depicted, includes four processing units 11, 21, 31, 41 in processor group 10. The processing units communicate with other components of system 100 via a system or fabric bus 50. Fabric bus 50 is connected to one or more service processors 60A, 60B, a system memory device 61, a memory controller 62, a shared or L3 system cache 66, and/or various peripheral devices 69. A processor bridge 70 can optionally be used to interconnect additional processor groups. Though not shown, it will be understood that the computer system 100 may also include firmware which stores the system's basic input/output logic, and seeks out and loads an operating system from one of the peripherals whenever the computer system is first turned on (booted).

Once loaded, the system memory device 61 (random access memory or RAM) stores program instructions and operand data used by the processing units, in a volatile (temporary) state, including the operating system 61A and application programs 61B. In addition, any peripheral device 69 may be connected to fabric bus 50 using any desired bus connection mechanism, such as a peripheral component interconnect (PCI) local bus using a PCI host bridge. A PCI bridge provides a low latency path through which processing units 11, 21, 31, 41 may access PCI devices mapped anywhere within bus memory or I/O address spaces. The PCI host bridge interconnecting peripherals 69 also provides a high bandwidth path to allow the PCI devices to access system memory 61. Such PCI devices may include, for example, a network adapter, a small computer system interface (SCSI) adapter providing interconnection to a permanent storage device (i.e., a hard disk), and an expansion bus bridge such as an industry standard architecture (ISA) expansion bus for connection to input/output (I/O) devices including a keyboard, a graphics adapter connected to a display device, and/or a graphical pointing device (e.g., mouse) for use with the display device. The service processor(s) 60 can alternately reside in a modified PCI slot which includes a direct memory access (DMA) path.

In a symmetric multi-processor (SMP) computer, all of the processing units 11, 21, 31, 41 are generally identical, that is, they all use a common set or subset of instructions and protocols to operate, and generally have the same architecture. As shown with processing unit 11, each processing unit may include one or more processor cores 16a, 16b which carry out program instructions in order to operate the computer. An exemplary processing unit would be the processor products marketed by Intel Corporation which comprise a single integrated circuit superscalar microprocessor having various execution units, registers, buffers, memories, and other functional units, which are all formed by integrated circuitry. The processor cores may operate according to reduced instruction set computing (RISC) techniques, and may employ both pipelining and out-of-order execution of instructions to further improve the performance of the superscalar architecture.

As depicted, each processor core 16a, 16b includes an on-board (L1) cache memory 18a, 18b (typically, separate instruction and data caches) that is constructed from high speed memory devices. Caches are commonly used to temporarily store values that might be repeatedly accessed by a processor, in order to speed up processing by avoiding the longer step of loading the values from system memory 61. A processing unit can include another cache such as a second level (L2) cache 12 which, along with a cache memory controller 14, supports both of the L1 caches 18a, 18b that are respectively part of cores 16a and 16b. Additional cache levels may be provided, such as an L3 cache 66 which is accessible via fabric bus 50. Each cache level, from highest (L1) to lowest (L3) can successively store more information, but at a longer access penalty. For example, the on-board L1 caches (e.g., 18a) in the processor cores (e.g., 16a) might have a storage capacity of 128 kilobytes of memory, L2 cache 12 might have a storage capacity of 4 megabytes, and L3 cache 66 might have a storage capacity of 32 megabytes. To facilitate repair/replacement of defective processing unit components, each processing unit 11, 21, 31, 41 may be constructed in the form of a replaceable circuit board, pluggable module, or similar field replaceable unit (FRU), which can be easily swapped, installed in, or swapped out of system 100 in a modular fashion.

As those skilled in the art will appreciate, a cache memory has many memory blocks which individually store the various instructions and data values. The blocks in any cache are divided into groups of blocks called sets or congruence classes. A set is the collection of cache blocks that a given memory block can reside in. For any given memory block, there is a unique set in the cache that the block can be mapped into, according to preset mapping functions. The number of blocks in a set is referred to as the associativity of the cache. Thus, information is stored in the cache memory in the form of cache lines or blocks, where an exemplary cache line (block) includes an address field, a state bit field, an inclusivity bit field, and a value field for storing the actual program instruction or operand data. The state bit field and inclusivity bit fields are used to maintain cache coherency in a multiprocessor computer system by indicating the validity of the value stored in the cache. The address field is a subset of the full address of the corresponding memory block. A compare match of an incoming address with one of the address fields (when the state field bits designate this line as currently valid in the cache) indicates a cache “hit.” The collection of all of the address fields in a cache (and sometimes the state bit and inclusivity bit fields) is referred to as a directory, and the collection of all of the value fields is the cache entry array.

As depicted in FIG. 1, the computer system 100 includes a plurality of memory sources, including the L1 cache memories (e.g., 18a, 18b, 48a, 48b) at each respective core (e.g., 16a, 16b, 46a, 46b), the L2 cache memories (e.g., 12, 42) at each respective processing unit (e.g., 11, 41), the shared L3 cache 66, and the buffer memory 64 at the memory controller 62. In order to use the temperature or power status to source a shared cache line, each memory source includes a temperature or power dissipation sensor which is used to signal its temperature or power status. Thus, a power/temperature sensor (e.g., 17a, 47a) is positioned at or within each L1 cache (e.g., 18a, 48a). In addition or in the alternative, a power/temperature sensor (e.g., 13, 43) is positioned at or within each L2 cache (e.g., 12, 42), a power/temperature sensor (e.g., 67) is positioned at or within each L3 cache 66, and/or a power/temperature sensor (e.g., 63) is positioned at or within each memory controller 62. In an example embodiment, each power/temperature sensor is formed as a diode which is placed to sense the temperature of the memory source, where the diode output voltage will vary from 0.5-1.0V for a typical temperature range of 20 to 100 C. To monitor the temperature for a given memory source, each memory source may include a storage device (e.g., a register) for storing the diode output voltage, or may continuously signal to the centralized directory 65 (described below) whether the memory source has crossed a temperature or power dissipation threshold. Thus, each core (e.g., 16a, 16b) monitors the power or temperature status information provided by its associated power/temperature sensor (e.g., 17a, 17b). In addition or in the alternative, each processing unit (e.g., 11, 41) monitors the power or temperature status information provided by the L2 cache power/temperature sensor (e.g., 13, 43), the L3 cache 66 monitors the power or temperature status information provided by the L3 cache power/temperature sensor 67, and/or the memory controller 62 monitors the power or temperature status information provided by the memory controller's power/temperature sensor 63.

In accordance with selected embodiments, the power dissipation or temperature status information is used to provide or intervene a shared cache line in a multi-processor system which implements a directory-based coherency protocol. To this end, the computer system 100 includes a centralized directory 65 at the memory controller 62 which coordinates the cache memory accesses by maintaining a list of all the cache memories that have a copy of the line and the line states. The centralized directory 65 includes directory logic which selects which core will return the line and signals that core to intervene the line to the requester. The centralized directory 65 also includes control logic which uses the power dissipation or temperature status information obtained from each memory source to select a “cool” memory source to provide a requested cache line that is shared by two or more memory sources, thereby avoiding “overheated” memory sources.

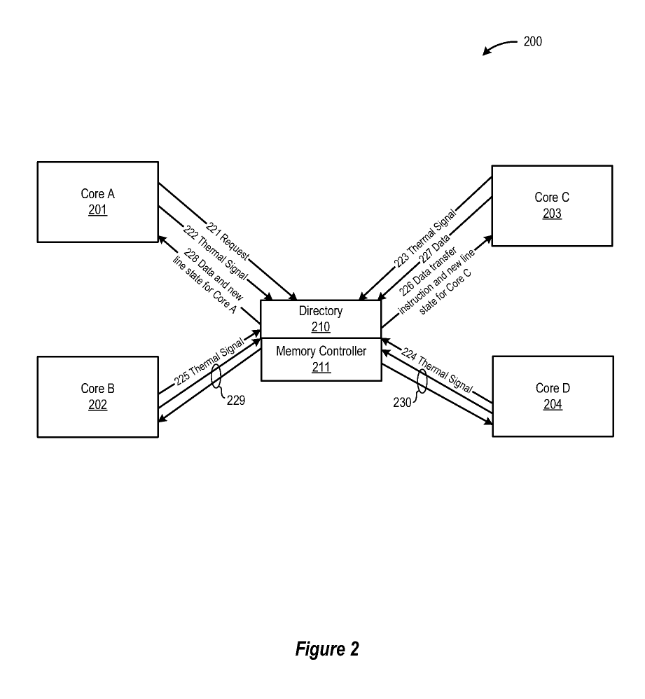

To further illustrate selected embodiments of the present invention where the power dissipation or temperature status information is used to provide or intervene a shared cache line in a multi-processor system which implements a directory-based coherency protocol, reference is now made to FIG. 2, which depicts an example signal flow between various cores in a multi-processor system 200 which implements power-aware line intervention in a directory-based coherency protocol for monitoring cache consistency. In the system 200, a plurality of cores 201, 202, 203, 204 are communicatively coupled to a memory controller 211. In a directory-based coherency protocol in a multiprocessor, a request for a cache line from a first core (e.g., 201) is sent to the centralized directory 210 which may be located in the memory controller 211 or elsewhere. The centralized directory structure 210 keeps a list of all the cores that have a copy of the line and the line states. In addition, the centralized directory structure 210 collects thermal signal information from each of the cores 201, 202, 203, 204 specifying the power dissipation or temperature status of each core. In response to a cache line request, the centralized directory logic selects which core will return the line using the thermal signal information line state information from the directory 210 to choose a source for the requested cache line by selecting a “cool” core or memory controller as the source. The selected source is instructed by the directory 210 to send the requested line, and the respective line state information in the directory and affected cores is updated accordingly.

In the example signal flow shown in FIG. 2, a first core 201 is requesting a cache line by sending an initial request 221 to the centralized directory 210. In initiating the request, the first core 201 is treated as the requestor core. Upon receiving the initial request 221, the centralized directory 210 has previously maintained line directory state information for each cache memory in the cores 201, 202, 203, 204, along with thermal signal information for each core. For example, if the second core 202 contains an invalid or modified copy of the requested cache line, the centralized directory 210 stores status information that identifies the specific core and its cache line status (e.g., “i” or “m,” where “i” indicates “invalid” and “m” indicates modified). Likewise, if the third core 203 contains a shared copy of the requested cache line, the centralized directory 210 stores status information that identifies the specific core and its cache line status (e.g., Core 203: s), where “s” indicates “shared.” In similar fashion, if the fourth core 204 contains an exclusive copy of the requested cache line, the centralized directory 210 stores status information that identifies the specific core and its cache line status (e.g., Core 204: e), where “e” indicates “exclusive.” Of course, two or more cores (e.g., cores 203 and 204) can contain a shared copy of a requested cache line, in which case the centralized directory 210 stores status information that identifies these cores having a shared or “s” cache line status.

As indicated above, each core may provide thermal signal information (T) for its associated memory source to the centralized directory 210, such as by sending thermal signals 222-225 to the centralized directory 210. In addition, the memory controller 211 may also provide its own thermal signal information to the directory 210. In an example embodiment, each core 201-204 in the multiprocessor and the memory controller 211 may continuously or regularly signal the directory 210 whether they have crossed the power dissipation threshold. This may be done using any desired monitoring and reporting scheme, such as comparing the output voltage from a power/thermal diode sensor to a predetermined threshold voltage to detect one of two states, such as H or L to signify a “high” or “low” temperature. In this case, a single bit can be used in the centralized directory 210 to store the thermal signal information, though additional bits can be used if additional thermal or power dissipation levels are required (i.e., very hot, hot, warm, and cool).

Upon receiving a cache line request (e.g., from core 201), the centralized directory 210 uses control logic to select which memory source 202, 203, 204, 211 will intervene the line to the requesting core 201. For example, the thermal signal bit(s) may be fed into the control logic/equations at the centralized directory 210 that determine which sharing core provides the line to the requesting master core. If two cores (e.g., 203, 204) share the line and one is “cool” and one is “hot”, the cool core (e.g., 203) would source the line. Once a memory source is selected, the centralized directory 210 generates and sends instructions to the selected memory source to provide the requested cache line to the requesting core, along with new line state information for the providing and requesting cores. In the example where the requested cache line is shared by two cores (e.g., 203 and 204), the centralized directory 210 would send a data transfer instruction 226 to the cool core 203 which may also include the new line state information for the requested cache line. In response, the source core 203 would provide the requested cache line (e.g., data message 227) to the directory 210, which would then forward the requested cache line data 228 to the requesting core 201, along with the new line state information for the requested cache line. As will be appreciated, the other cores can also receive instructions and transfer data, as indicated at 229, 230. As will be appreciated, if there are two or more “cool” cores that can source a shared line, any desired tie-breaking rule may be used to select the line source. And if all sharing cores are hot, and the data is in a buffer of the memory controller 211, the memory controller 211 may source the line.

In response to the directory response instruction 226, the providing core updates its line directory state for the requested cache line to reflect any change in status caused by the selection of a source for the requested cache line. In similar fashion, the line directory state at the requesting core is also updated in response to the directory's data transfer message 228. For example, if a read request for a cache line is received by a memory source that currently stores an invalid copy of the cache line, then that memory source will not be selected as the source, and the line directory state remains “invalid.” Instead, the requested line will be obtained from the memory controller, in which case the line directory state for the requesting core is updated as “exclusive.” But if a read request for a cache line is received by a memory source that currently stores a modified copy of the cache line and that memory source is selected on the basis of the thermal information to intervene the cache line, then the line directory state for the cache line in the provider core is updated as “invalid” and the line directory state for the requesting core is updated as “modified.” And if a read request for a cache line is received by a memory source that currently stores a shared or exclusive copy of the cache line and that memory source is selected on the basis of the thermal information as to intervene the cache line, then the line directory state for the cache line in the provider core is updated as “shared” (or alternatively, “invalid”) and the line directory state for the requesting core is updated as “shared” (if obtained from a “shared” provider core) or “exclusive” (if obtained from an “exclusive” provider core).

As for requests to write to a cache line not already stored in shared, exclusive or modified form in the requesting core, the line directory state for the cache line in that providing core is updated as “invalid” in response to data transfer message, while the line directory state for the cache line in that requesting core is updated as “exclusive” in response to data transfer message, unless it was obtained from a “modified” provider core, in which case the line directory state for the cache line in that requesting core is updated as “modified.” If the line to be written is already “shared” in the requesting core, then a Dclaim is issued to the directory, which invalidates the line in the other sharers, and the line is updated as “modified” in the requesting core and directory. If the line exists as “exclusive” in the requesting core, it is upgraded to “modified” in the requesting core and the directory is informed. If the line is already “modified” in the requesting core, then no Dclaim or upgrade requests need be issued.

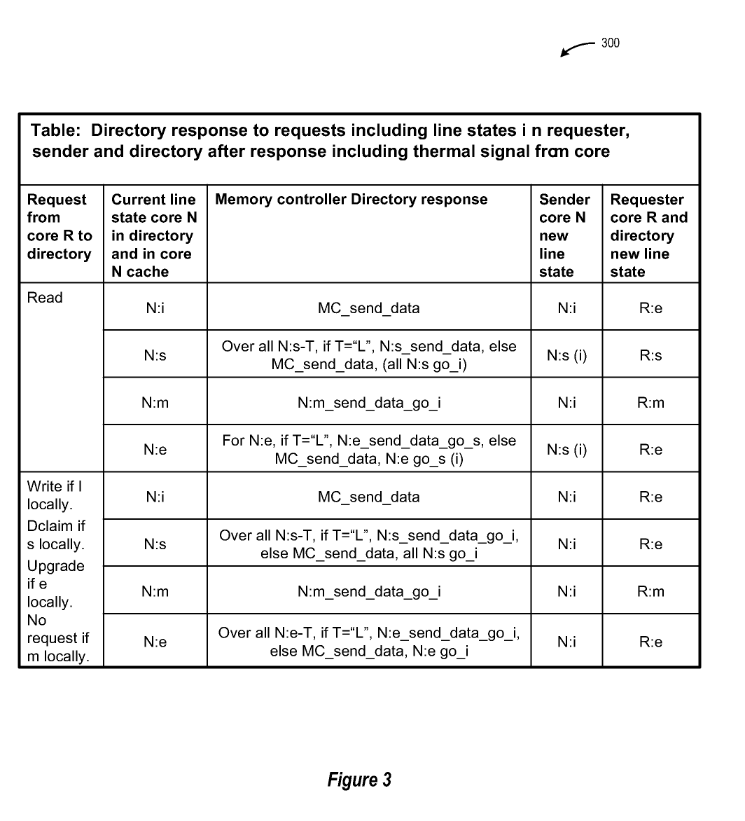

It will be appreciated that the substance of the foregoing signaling scheme may be implemented with a variety of command structures and control logic equations, and yet still provide the power-aware line intervention benefits in a directory-based coherency protocol for monitoring cache consistency. As but one example implementation, FIG. 3 provides an example table listing 300 of directory responses to the requesting and sending cores in response to a read or write request from a requesting core in a multi-processor system which implements power-aware line intervention in selected directory-based coherency protocol embodiments of the present invention. In the first table column, the type of cache line request (e.g., read or write) is specified. In the second column, the current state of the requested cache line at each memory source is specified as invalid (i), shared (s), modified (m) or exclusive (e). In addition, the second column specifies the current thermal or power dissipation status detected at each memory source as either low (L) or high (H) temperature, though other thermal conditions could be specified. In the third column, the directory response that is generated based on the values contained in the second column is represented as an instruction to provide the requested data and update the appropriate line directory state information. Finally, the fourth column specifies the new line directory state (i, s, m, e) for the providing core (N) after the requested cache line is provided, while the fifth column specifies the new line directory state (i, s, m, e) for the requesting core (R) after the requested cache line is provided.

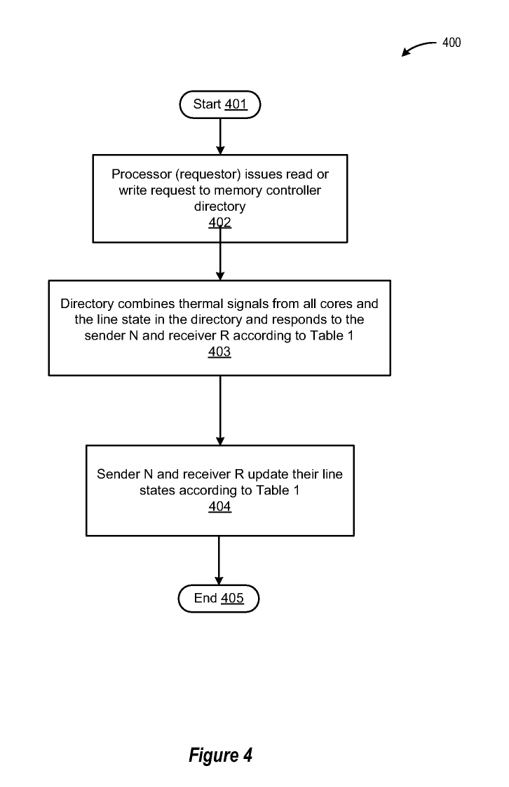

To further illustrate selected embodiments of the present invention, FIG. 4 is a logical flowchart of the directory-based coherency protocol steps 400 used to source a cache line to a requesting core from a plurality of memory sources in a multi-processor system based on the power or thermal conditions associated with the memory resources. At step 401, the process starts, such as when a requesting core or processor is running a program that requires data from memory. When a memory access is required, the requesting core/processor issues a read or write request to the central directory, which may be located centrally at a memory controller (step 402). In response, the central directory combines the thermal signal information (previously collected from the other cores) and the line state information for each core to choose which responding core will provide the requested cache line by using the thermal signal information to choose from among the “cool” cores (step 403). For example, the directory response may take the form of a directory response message such as set forth in the third column of table listing 300. When the directory response is received, the chosen provider core sends the requested cache line to the requesting core, and the directory lines states for each core are updated at the requesting and providing core, as well as at the central directory (step 404), and the process ends (step 405) until another memory access is required.

As described herein, program instructions or code for sourcing a requested cache line from a low-power or “cool” memory source may execute on each core where a memory source is located and/or in a centralized location, such as a memory controller. For example, each cache memory (e.g., L1, L2, L3) and memory controller in a multiprocessor system may have its own programming instructions or code for monitoring its thermal or power dissipation status, and for distributing that status information to the appropriate control logic for use in selecting the low-power source for requested data. The control logic may be centrally located at a single location (such as a memory controller), or may be distributed throughout the multiprocessor system so that the control logic is shared.

The power-aware line intervention techniques disclosed herein for a multiprocessor data processing system use a directory-based coherency protocol to source cache lines based on the temperature and/or power status of each cache memory. By using a centralized directory-based coherency approach, the power-aware line intervention may be easily scaled to additional processors, and may be implemented using less bandwidth and without requiring additional bus bits than would be required with snoop coherency protocols.

As will be appreciated by one skilled in the art, the present invention may be embodied in whole or in part as a method, system, or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product on a computer-usable storage medium having computer-usable program code embodied in the medium. For example, the functions of selecting a low power or low temperature memory source to intervene a requested cache line that is shared by a plurality of memory sources may be implemented in software that is stored in each candidate memory source or may be centrally stored in a single location.

The foregoing description has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification and example implementations provide a complete description of the manufacture and use of the composition of the invention. Since many embodiments of the invention can be made without departing from the spirit and scope of the invention, the invention resides in the claims hereinafter appended.

What is claimed is:

1. A method for intervening a shared cache line in a multiprocessor data processing system, comprising:
generating a request from a requesting processor core for a first cache line during operation of said multiprocessor data processing system;
identifying at a centralized directory a plurality of memory sources which store a copy of the requested first cache line in response to receiving the request for the first cache line;
maintaining at the centralized directory line state information, along with temperature or power dissipation values, for each of the plurality of memory sources;
selecting a first memory source from the plurality of memory sources to intervene the requested first cache line, where the first memory source is selected at least in part based on having an acceptable temperature or power dissipation value; and
sending from the centralized directory a selection message to instruct the first memory source to intervene the requested first cache line.

2. The method of claim 1, where selecting a first memory source comprises selecting a first memory source having a first temperature or power dissipation value that is lower than a second temperature or power dissipation value associated with a second memory source.

3. The method of claim 1, where selecting a first memory source comprises selecting a cool memory source based at least in part on comparing a first temperature or power dissipation value that is associated with the first memory source to one or more other temperature or power dissipation values associated with one or more other memory sources.

4. The method of claim 1, where the plurality of memory sources comprises a plurality of cache memories.

5. The method of claim 1, where each of the plurality of memory sources comprises a sensor for measuring a temperature or power dissipation value associated with said memory source.

6. The method of claim 4, where selecting a first memory source comprises selecting a memory controller having an acceptable temperature or power dissipation value to intervene the requested first cache line if none of the plurality of cache memories has an acceptable temperature or power dissipation value.

7. The method of claim 1, where maintaining at the centralized directory line state information, along with temperature or power dissipation values, comprises sending from each memory source a signal indicating if the memory source has crossed a predetermined power or thermal threshold.

8. The method of claim 1, further comprising invalidating line state information in the centralized directory for the plurality of memory sources when the request from the requesting processor core comprises a request for exclusive access to the first cache line.

9. A computer-usable medium embodying computer program code, the computer program code comprising computer executable instructions configured for intervening a shared cache line in a multiprocessor data processing system by:
generating a request from a requesting processor core for a first cache line during operation of said multiprocessor data processing system;
identifying at a centralized directory a plurality of memory sources which store a copy of the requested first cache line in response to receiving the request for the first cache line;
maintaining at the centralized directory line state information, along with temperature or power dissipation values, for each of the plurality of memory sources;
selecting a first memory source from the plurality of memory sources to intervene the requested first cache line, where the first memory source is selected at least in part based on having an acceptable temperature or power dissipation value; and
sending from the centralized directory a selection message to instruct the first memory source to intervene the requested first cache line.

10. The computer-usable medium of claim 9, where selecting a first memory source comprises selecting a first memory source having a first temperature or power dissipation value that is lower than a second temperature or power dissipation value associated with a second memory source.

11. The computer-usable medium of claim 9, where selecting a first memory source comprises selecting a cool memory source based at least in part on comparing a first temperature or power dissipation value that is associated with the first memory source to one or more other temperature or power dissipation values associated with one or more other memory sources.

12. The computer-usable medium of claim 9, where the plurality of memory sources comprises a plurality of cache memories.

13. The computer-usable medium of claim 9, where each of the plurality of memory sources comprises a sensor for measuring a temperature or power dissipation value associated with said memory source.

14. The computer-usable medium of claim 12, where selecting a first memory source comprises selecting a memory controller having an acceptable temperature or power dissipation value to intervene the requested first cache line if none of the plurality of cache memories has an acceptable temperature or power dissipation value.

15. The computer-usable medium of claim 9, where maintaining at the centralized directory line state information, along with temperature or power dissipation values, comprises sending from each memory source a signal indicating if the memory source has crossed a predetermined power or thermal threshold.

16. The computer-usable medium of claim 9, further comprising invalidating line state information in the centralized directory for the plurality of memory sources when the request from the requesting processor core comprises a request for exclusive access to the first cache line.

17. A multiprocessor data processing system comprising:
a plurality of processors, each comprising one or more cache memories;
a data bus coupled to the plurality of processors;
a computer-usable medium embodying computer program code, the computer-usable medium being coupled to the data bus, the computer program code comprising instructions for intervening a shared cache line in a multiprocessor data processing system by:
generating a request from a requesting processor core for a first cache line during operation of said multiprocessor data processing system;
identifying at a centralized directory a plurality of cache memories which store a copy of the requested first cache line in response to receiving the request for the first cache line;
maintaining at the centralized directory line state information, along with temperature or power dissipation values, for each of the plurality of cache memories;
selecting a first cache memory from the plurality of cache memories to intervene the requested first cache line, where the first cache memory is selected at least in part based on having an acceptable temperature or power dissipation value; and
sending from the centralized directory a selection message to instruct the first cache memory to intervene the requested first cache line.

18. The data processing system of claim 17, where selecting a first cache memory comprises selecting a first cache memory having a first temperature or power dissipation value that is lower than a second temperature or power dissipation value associated with a second cache memory.

19. The data processing system of claim 17, further comprising a sensor positioned at each cache memory for measuring a temperature or power dissipation value associated with said cache memory.

20. The data processing system of claim 17, where the sensor comprises a diode.
